(19) United States
(12) Patent Application Publication
(10) Pub. No.: US 2006/0043589 A1
(43) Pub. Date: Mar. 2, 2006

(54) Electronic device and method for fabricating the same

(76) Inventor: Akihisa Iwasaki, Toyama (JP)

Correspondence Address: MCDERMOTT WILL & EMERY LLP, 600 13TH STREET, N.W., WASHINGTON, DC, 20005-3096, US

(21) Appl. No.: 11/199,158

(22) Filed: Aug. 9, 2005

(30) Foreign Application Priority Data
Aug. 24, 2004 (JP) 2004-243260

(51) Int. Cl. H01L 23/52

(52) U.S. Cl. 257/751

(57) ABSTRACT

An electronic device includes: a lower interconnect formed to fill a recess of a first insulating film; a barrier film formed at least on the lower interconnect; and a second insulating film formed on the first insulating film and the barrier film. The first and second insulating films are bonded to each other.

### CROSS-REFERENCE TO RELATED APPLICATIONS

The disclosure of Japanese Patent Application No. 2004-243260 filed on Aug. 24, 2004 including specification, drawing and claims is incorporated herein by reference in its entirety.

### BACKGROUND OF THE INVENTION

(1) Field of the Invention

The present invention relates to an electronic device and a method for fabricating the same, and more particularly relates to a high-reliability copper interconnect structure formed using a damascene process and a method for forming the same.

(2) Description of Related Art

In recent years, with increasing integration level of semiconductor integrated circuits and reducing chip size, miniaturization of interconnects and increase in the number of interconnect layers have advanced at an increasingly fast rate. The attendant reduced distance between interconnects now makes it impossible to neglect RC delays due to increase in the interconnect resistance and capacitance. Therefore, in order to advance further miniaturization of semiconductor integrated circuits, it has been necessary to reduce electrical parasitic capacitances between interconnects. In order to reduce electrical parasitic capacitances between interconnects, it is necessary to reduce the specific resistance of a material of interconnects and the relative permeability of an interlayer insulating film used.

For 0.13-μm node devices, in order to reduce the specific resistance of a material of interconnects, interconnects have been changed from aluminum interconnects to copper interconnects formed using a damascene process. The use of copper interconnects formed using a damascene process can reduce the specific resistance of the material of interconnects and improve the migration resistance of interconnects. However, copper (Cu) atoms of copper interconnects enter into transistors, leading to the breakdown of transistors. The reason for this is that Cu atoms diffuse into insulating films including a silicon dioxide film (SiO₂) at high speed. Therefore, it is necessary to form, around a copper film for an interconnect, a barrier film for preventing copper from diffusing between interconnects.

At present, in order to cover the periphery of a copper interconnect, typically, a conductive barrier film (barrier metal film) functioning as a film for preventing the diffusion of copper.

An insulating film having a smaller relative permeability than the silicon oxide film containing fluorine is required for 90-nm or smaller node devices (hereinafter, an insulating film with a relative permeability (ε) of 3.5 or less is referred to as a low-k film). An electronic device using a low-k film and a fabrication method for the same are disclosed in, for example, Japanese Unexamined Patent Publication No. 2003-309174 (Claims 1 through 10, FIGS. 2 through 7).

A known electronic device and a fabrication method for the same will be described hereinafter with reference to FIGS. 9 and 10A through 10F.

FIG. 9 is a cross-sectional view showing the structure of an exemplary known copper interconnect, more particularly, a cross-sectional view showing the structure of a copper interconnect having a dual damascene structure.

As shown in FIG. 9, a first interlayer insulating film 101 is formed on a substrate (not shown) to have a groove 101a for a lower interconnect (hereinafter, referred to as “lower interconnect groove 101a”). A lower interconnect 102 obtained by stacking a first barrier metal film 102a and a first copper film 102b in this order is formed in the lower interconnect groove 101a of the first interlayer insulating film 101. An insulative barrier film 103 is formed on the lower interconnect 102 and the first interlayer insulating film 101. A second interlayer insulating film 104 is formed on the insulative barrier film 103. Contact holes 104a are formed in the lower part of the second interlayer insulating film 104 and the insulating barrier film 103 to expose the top surface of the lower interconnect 102, and grooves 104b for upper interconnects (hereinafter, referred to as “upper interconnect grooves 104b”) are formed in the upper part of the second interlayer insulating film 104 to communicate with the contact holes 104a. Upper interconnects 106 each composed of the upper part of a second barrier metal film 106a and the upper part of a second copper film 106b are formed in the upper interconnect grooves 104b. Plugs 106c each composed of the lower part of the second barrier metal film 106a and the lower part of the second copper film 106b are formed in the contact holes 104a, and the lower interconnect 102 is electrically connected through the plugs 106c to the upper interconnects 106.

FIGS. 10A through 10F are cross-sectional views showing process steps in an exemplary known method for forming a copper interconnect, and more particularly illustrates process steps for forming a copper interconnect by a dual damascene process in which a second interlayer insulating film is formed with contact holes and upper interconnect grooves which are both to be connected to a lower interconnect, the contact holes and the upper interconnect grooves are concurrently filled with copper films and parts of the copper films located outside the upper interconnect grooves are polished away.

First, as shown in FIG. 10A, a first interlayer insulating film 101 composed of, for example, a silicon oxide film containing carbon is formed on a substrate (not shown). Subsequently, a resist pattern (not shown) is formed on the first interlayer insulating film 101 to have a pattern for a lower interconnect groove by photolithography, and then the first interlayer insulating film 101 is subjected to dry etching using the resist pattern as a mask, thereby forming a lower interconnect groove 101a. Next, a first barrier metal film 102a made of a Ta/TaN multilayer film and a copper seed film (not shown) are successively deposited on the first interlayer insulating film 101 by sputtering to fill halfway the lower interconnect groove 101a formed in the first interlayer insulating film 101. Subsequently, a first copper film 102b is deposited on the copper seed film by electrolytic plating to completely fill the lower interconnect groove 101a. Respective parts of the first barrier metal film 102a and the first copper film 102b located outside the lower interconnect groove 101a are removed by CMP (hereinafter, these two films are considered as a multilayer including also the copper seed film interposed therebetween), thereby forming a lower interconnect 102 composed of the first barrier metal film 102a and the first copper film 102b. The lower interconnect 102 has the same configuration as an upper interconnect 106 (see FIG. 10F) formed in a later-described step.

Next, as shown in FIG. 10B, an insulative barrier film 103 functioning as a film for preventing the diffusion of copper and made of a silicon carbide film or the like is deposited on the lower interconnect 102 and the first interlayer insulating film 101 to have a thickness of approximately 50 nm. Subsequently, a second interlayer insulating film 104 made of, for example, a silicon oxide film containing carbon is deposited on the insulative barrier film 103 to have a thickness of approximately 600 nm.

Next, as shown in FIG. 10C, a cap film 105 made of, for example, a silicon oxide film is deposited on the second interlayer insulating film 104 to have a thickness of approximately 50 nm. The cap film 105 is completely removed in the later-described step of executing CMP. Subsequently, a resist pattern (not shown) having a pattern for contact holes is formed on the cap film 105 by photolithography, and then the cap film 105 and the second interlayer insulating film 104 are subjected to dry etching using the resist pattern as a mask. In this way, contact holes 104a are formed to pass through the cap film 105 and the second interlayer insulating film 104 and reach the insulative barrier film 103.

Next, as shown in FIG. 10D, like the method for forming the contact holes 104a, upper interconnect grooves 104b communicating with the contact holes 104a are formed in the upper part of the second interlayer insulating film 104 by opening the cap film 105 and the second insulating film 104 using photolithography and dry etching.

Next, as shown in FIG. 10E, a substrate region is entirely subjected to anisotropic etching, thereby removing parts of the insulative barrier film 103 exposed at the bottoms of the contact holes 104a to partly expose the top surface of the lower interconnect 102.

Next, as shown in FIG. 10F, a second barrier metal film 106a made of a Ta/TaN multilayer film and a copper seed film (not shown) are successively deposited on the second interlayer insulating film 104 by sputtering to fill halfway each contact hole 104a and the associated upper interconnect groove 104b. Subsequently, a second copper film 106b is deposited on the copper seed film by electrolytic plating to completely fill the contact hole 104a and the upper interconnect groove 104b. Next, the cap film 105, respective parts of the second barrier metal film 106a and the second copper film 106b located outside the upper interconnect groove 104b are removed by CMP (hereinafter, these two films are considered as a multilayer including also the copper seed film interposed therebetween). In this way, upper interconnects 106 are formed, each composed of an upper part of a second barrier metal film 106a and an upper part of a second copper film 106b. Plugs 106c each composed of a lower part of a second barrier metal film 106a and a lower part of a second copper film 106b are formed in the contact holes 104a, respectively, and the lower interconnect 102 is electrically connected through the plugs 106c to the upper interconnects 106. The second barrier metal film 106a formed on the bottom and side surfaces of the second copper film 106b with which a contact hole 104a and an upper interconnect groove 104b are filled functions as a film for preventing the diffusion of copper.

The above-described fabrication process steps, i.e., the process steps in the known method for fabricating an electronic device as shown in FIGS. 10A through 10F are repeated, thereby obtaining a known electronic device having a multilayer copper interconnect.

### SUMMARY OF THE INVENTION

In the above-described known interconnect structure, the interface between the insulative barrier film and the first interlayer insulating film and the interface between the insulative barrier film and the second interlayer insulating film inevitably have a structure in which a hydrophilic film is bonded to a hydrophobic film. This deteriorates the adhesion between the films at the interfaces, leading to the separation of the films at the interfaces.

In view of the above, it is an object of the present invention to provide an electronic device that does not lead to the above-described separation of films at the interface between the films and a method for fabricating the same.

In order to achieve the above object, the present invention has been made based on the following finding: An electronic device using a low-k film (a hydrophobic film) has an interface between a hydrophilic film, such as SiC, used as a barrier film and a hydrophobic film, which is the low-k film. To cope with this, in the present invention, an interface between a hydrophilic film and another hydrophilic film or an interface between a hydrophobic film and another hydrophobic film is formed in the vicinity of a barrier film to prevent the separation between a hydrophilic film and a hydrophobic film at the interface therebetween.

More particularly, an electronic device of the present invention includes: a lower interconnect formed to fill a recess of a first insulating film; a barrier film formed at least on the lower interconnect; and a second insulating film formed over the first insulating film and the barrier film, wherein the first and second insulating films are bonded to each other.

According to the electronic device of the present invention, since the first and second insulating films are bonded to each other, this can improve the adhesion between the first and second insulating films at their interface. This can prevent the separation between the first insulating film and the second insulating film at their interface. The insulating films can be restrained from being separated from the barrier film at the interface therebetween as described in the known example.

In the electronic device of the present invention, the interface at which the first and second insulating films are bonded to each other is preferably located below the top surface of the lower interconnect.

Thus, the interface at which the first and second insulating films are bonded to each other and which serves as a path through which copper is likely to diffuse from the lower interconnect into the insulating films is located below the top surface of the lower interconnect. Therefore, copper can be restrained from diffusing from the lower interconnect into the insulating films. This can improve the reliability of the copper interconnect.

In the electronic device of the present invention, the barrier film is preferably formed to cover part of the side surface of the lower interconnect located at a higher level than the interface at which the first and second insulating films are bonded to each other.

Since part of a barrier film thus forms a sidewall on the side surface of the lower interconnect, this increases the length of the interface at which copper diffuses from the lower interconnect into the insulating films. Therefore, copper can be restrained from diffusing from the lower interconnect into the insulating films. More particularly, since the interface between the lower interconnect and the second insulating film, at which copper diffuses from the lower interconnect into the insulating films is completely covered with part of the barrier film serving as a sidewall, this increases the energy gap beyond which copper atoms should go to diffuse into the insulating films. Therefore, copper can be restrained from diffusing from the lower interconnect into the insulating films. This can improve the reliability of the copper interconnect.

In the electronic device of the present invention, the interface at which the first and second insulating films are bonded to each other is preferably uneven.

Since the interface at which the first and second insulating films are bonded to each other is thus uneven, this increases the area in which the first insulating film comes into contact with the second insulating film at their interface. Therefore, the adhesion at their interface is sharply improved. In addition, copper can be restrained from diffusing into the insulating films because of the increased length of the interface between the first and second insulating films, which serves as a path through which copper diffuses into the insulating films, i.e., the increased distance over which copper diffuses. This can improve the reliability of the copper interconnect.

It is preferable that, in the electronic device of the present invention, for the surface roughness of the interface at which the first and second interlayer insulating films are bonded to each other, the arithmetic average roughness Rₐ thereof is 4 nm or less or the maximum height Rₘₐₓ thereof is 50 nm or less.

Since an interface between the first and second insulating films is formed to have greater roughness than a normal interface, this can improve the adhesion at the interface therebetween and restrain copper from diffusing into the insulating films.

In the electronic device of the present invention, the first and second insulating films are preferably composed of films with the same properties, and the first and second insulating films are further preferably composed of hydrophobic films or hydrophilic films.

This can further improve the adhesion between the first and second insulating films.

In the electronic device of the present invention, the barrier film is preferably formed only on the lower interconnect.

Since a barrier film with a high permittivity is not formed on the first insulating film, this significantly reduces the interconnect capacitance. Therefore, the problem of an interconnect delay for an electronic device can be solved.

In the electronic device of the present invention, the barrier film is preferably an insulative barrier film made of any one selected from the group of SiN, SiCN, SiC, SiCH, and BCB or a conductive barrier film made of any one selected from the group of CoWP and CoWB.

It is preferable that the electronic device of the present invention further includes an upper interconnect formed in the second insulating film and electrically connected to the lower interconnect.

It is preferable that, in the electronic device of the present invention, the upper interconnect is electrically connected to the lower interconnect through a plug whose lower end is connected to the lower interconnect and whose upper end is connected to the upper interconnect.

In the electronic device of the present invention, the lower interconnect preferably has a copper interconnect structure in which its surfaces excluding its top surface are covered with a barrier metal layer.

In the electronic device of the present invention, the length obtained by summing the width of the lower interconnect and the distance between the lower interconnect and an interconnect adjacent to the lower interconnect is preferably 0.4 μm or less.

It is preferable that, in the electronic device of the present invention, the height of the lower interconnect is preferably 250 nm or less and the interface at which the first and second interlayer insulating films are bonded to each other is located 10 nm or more below the top surface of the lower interconnect.

In the electronic device of the present invention, the first interlayer insulating film is preferably made of a film having a low permittivity of 2.4 or less.

A method for fabricating an electronic device of the present invention includes the steps of: forming a recess in a first interlayer insulating film; forming a conductive pattern to fill the recess; forming a barrier film at least on the conductive pattern; and forming a second insulating film on the first insulating film and the barrier film, wherein the step of forming the second insulating film is carried out to produce an interface at which the first and second insulating films are bonded to each other.

According to the fabrication method for an electronic device of the present invention, since there exists the interface at which the first and second insulating films are bonded to each other, this can improve the adhesion between the first and second insulating films at their interface. This can prevent the separation between the first insulating film and the second insulating film at their interface. The insulating films can be restrained from being separated from the barrier film at the interface therebetween as described in the known example.

In the method of the present invention, the step of forming the barrier film preferably includes the step of depositing the barrier film on the first insulating film and the conductive pattern, then forming a resist pattern to mask an area occupied by the conductive pattern, and selectively removing the deposited barrier film using the resist pattern.

Since a barrier film is thus formed only on the conductive pattern and a barrier film with a high permittivity is not formed on the first insulating film, this significantly reduces the interconnect capacitance. Therefore, the problem of an interconnect delay for an electronic device can be solved.

In the method of the present invention, the step of forming the barrier film is preferably carried out using selective CVD.

Since this makes it possible that a barrier film is formed only on the conductive pattern and a barrier film with a high permittivity is not formed on the first insulating film, the interconnect capacitance can be significantly reduced. Therefore, the problem of an interconnect delay for an electronic device can be solved.

In the method of the present invention, the interface at which the first and second insulating films are bonded to each other is preferably formed so as to be located below the top surface of the conductive pattern.

Thus, the interface at which the first and second insulating films are bonded to each other and which serves as a path through which copper is likely to diffuse from the lower interconnect into the insulating films is located below the top surface of the lower interconnect. Therefore, copper can be restrained from diffusing from the lower interconnect into the insulating films. This can improve the reliability of the copper interconnect.

In the method of the present invention, the step of forming the conductive pattern preferably includes the step of depositing a conductive film to fill the recess and then removing part of the conductive film located outside the recess using a polishing slurry with a higher removal rate for the first insulating film than that for the conductive film.

Thus, the interface at which the first and second insulating films are bonded to each other can be formed so as to be located below the top surface of the conductive pattern.

It is preferable that the method of the present invention further includes the step of, after the step of forming the conductive pattern and before the step of forming the barrier film, selectively removing the exposed top surface of the first insulating film.

Thus, the interface at which the first and second insulating films are bonded to each other can be formed so as to be located below the top surface of the conductive pattern.

In the method of the present invention, the step of selectively removing the exposed top surface of the first insulating film is preferably carried out by a plasma process or a cleaning process using a chemical solution.

In the method of the present invention, the plasma process is preferably carried out using a plasma made of any one or more selected from the group of O₂, H₂, H₂O, N₂, He, and NH₃.

In the method of the present invention, the cleaning process using the chemical solution is preferably carried out using a chemical solution of HF or a chemical solution of a polymer containing quarternary ammonium salt.

In the method of the present invention, in the step of forming the barrier film, the barrier film is preferably formed to cover part of the side surface of the lower interconnect located at a higher level than the top surface of the first insulating film.

Since part of a barrier film thus forms a sidewall on the side surface of the lower interconnect, this increases the length of the interface at which copper diffuses from the lower interconnect into insulating films. Therefore, copper can be restrained from diffusing from the lower interconnect into insulating films. More particularly, since the interface between the lower interconnect and the second insulating film, at which copper diffuses from the lower interconnect into the insulating films is completely covered with part of the barrier film serving as a sidewall, this increases the energy gap beyond which copper atoms should go to diffuse into films. Therefore, copper can be restrained from diffusing from the lower interconnect into insulating films. This can improve the reliability of the copper interconnect.

In the method of the present invention, the interface at which the first and second insulating films are bonded to each other is preferably formed to become uneven.

Since the interface at which the first and second insulating films are bonded to each other is thus uneven, this increases the area in which the first insulating film comes into contact with the second insulating film at their interface. Therefore, the adhesion at their interface is sharply improved. In addition, copper can be restrained from diffusing into the insulating films because of the increased length of the interface between the first and second insulating films, which serves as a path through which copper diffuses into the insulating films, i.e., the increased distance over which copper diffuses. This can improve the reliability of the copper interconnect.

In the method of the present invention, the step of forming the conductive pattern preferably includes the step of depositing a conductive film to fill the recess, removing part of the conductive film located outside the recess, and then polishing the exposed top surface of the first insulating film using slurry with an abrasive grain density of 20 wt % or more.

Since the exposed top surface of the first insulating film can thus be formed to become uneven, the interface between the first and second insulating films can be formed to become uneven.

It is preferable that the method of the present invention further includes the step of, after the step of forming the conductive pattern and before the step of forming the barrier film, subjecting the exposed top surface of the first insulating film to a plasma process.

Since the exposed top surface of the first insulating film can thus be formed to become uneven, the interface between the first and second insulating films can be formed to become uneven.

In the method of the present invention, the plasma process is preferably carried out using a mixed gas of Ar and H₂, a mixed gas of Ar and He, a mixed gas of NH₃ and He, or a mixed gas of NH₃ and H₂.

### BRIEF DESCRIPTION OF THE DRAWINGS

FIG. 1 is a cross-sectional view showing the structure of the principal part of an electronic device according to a first embodiment of the present invention.

FIGS. 2A through 2G are cross-sectional views showing process steps in a fabrication method for an electronic device according to the first embodiment of the present invention.

FIG. 3 is a cross-sectional view showing the structure of the principal part of an electronic device according to a second embodiment of the present invention.

FIGS. 4A through 4G are cross-sectional views showing process steps in a fabrication method for an electronic device according to the second embodiment of the present invention.

FIG. 5 is a cross-sectional view showing the structure of an electronic device according to a third embodiment of the present invention.

FIGS. 6A through 6G are cross-sectional views showing process steps in a fabrication method for an electronic device according to the third embodiment of the present invention.

FIG. 7 is a cross-sectional view showing the structure of an electronic device according to a fourth embodiment of the present invention.

FIGS. 8A through 8G are cross-sectional views showing process steps in a fabrication method for an electronic device according to a fourth embodiment of the present invention.

FIG. 9 is a cross-sectional view showing the structure of an electronic device according to a known example.

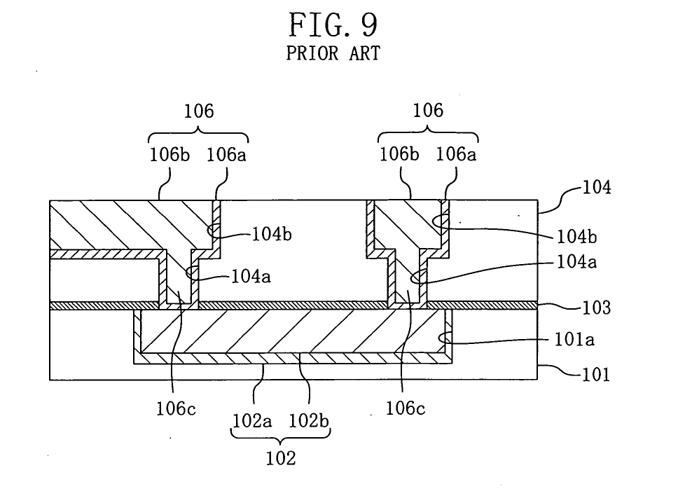

FIGS. 10A through 10F are cross-sectional views showing process steps in a fabrication method for an electronic device according to the known example.

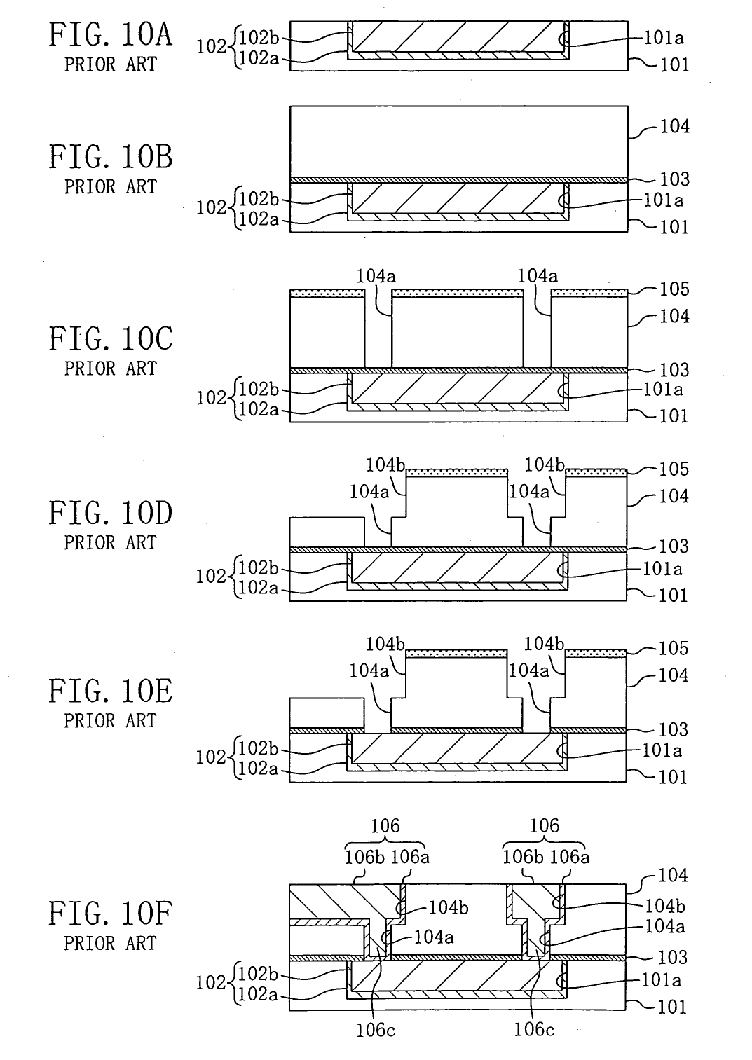

### DETAILED DESCRIPTION OF THE INVENTION

Embodiments of the present invention will be described hereinafter with reference to the drawings.

### Embodiment 1

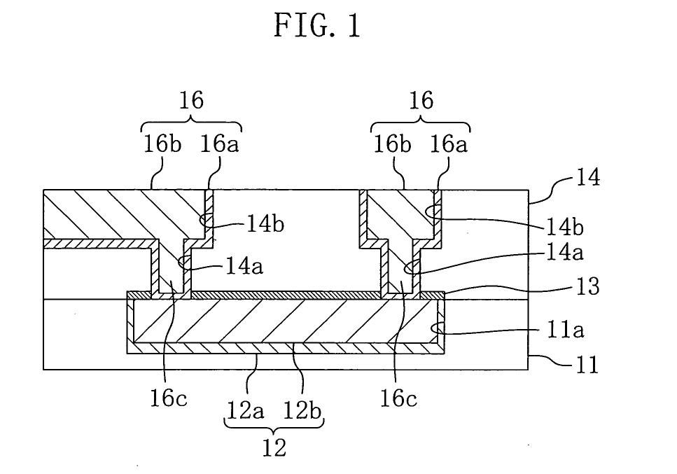

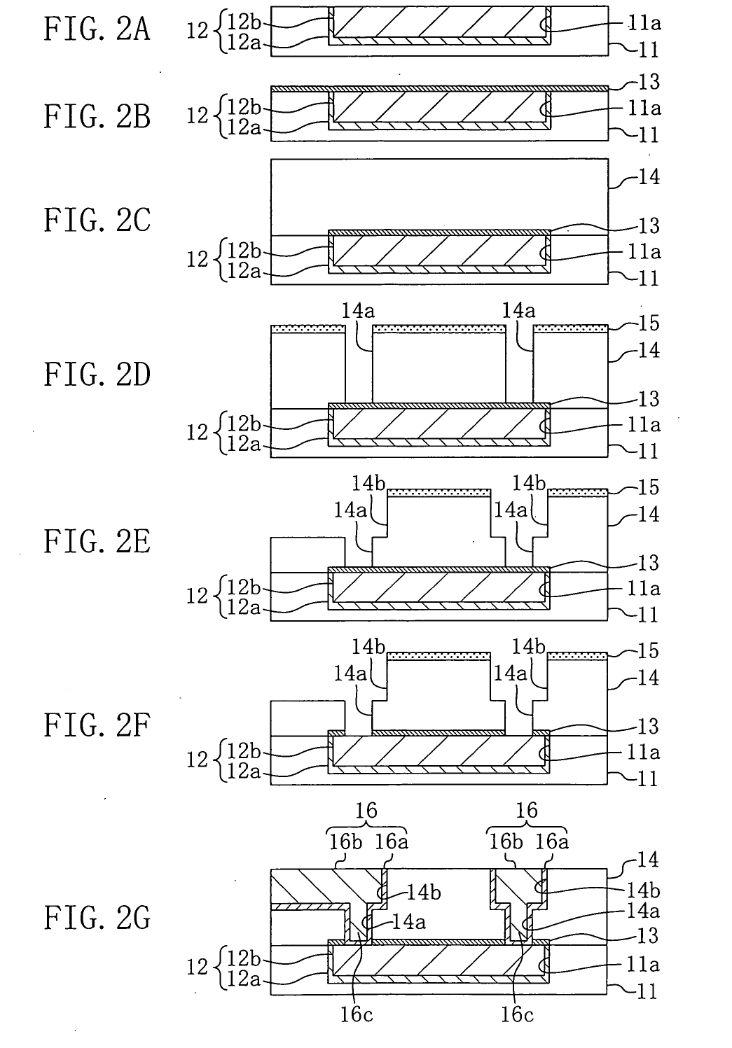

An electronic device according to a first embodiment of the present invention and a fabrication method for the same will be described hereinafter with reference to FIGS. 1 and 2A through 2G.

FIG. 1 is a cross-sectional view showing the structure of an electronic device according to a first embodiment of the present invention.

As shown in FIG. 1, a hydrophobic first interlayer insulating film 11 is formed on a silicon substrate (not shown) to have a lower interconnect groove 11a. A lower interconnect 12 obtained by stacking a first barrier metal film 12a and a first copper film 12b in this order is formed in the lower interconnect groove 11a of the first interlayer insulating film 11. A hydrophilic barrier film 13 functioning as a film for preventing the diffusion of copper into the later-described hydrophobic second interlayer insulating film 14 or a conductive barrier film 13 of, for example, CoWP (cobalt tungsten phosphide) is formed on the lower interconnect 12.

A hydrophobic second interlayer insulating film 14 is formed on the first interlayer insulating film 11 and the barrier film 13. Contact holes 14a are formed in the lower part of the second interlayer insulating film 14 and the barrier film 13 to partly expose the top surface of the lower interconnect 12. In addition, upper interconnect grooves 14b are formed in the upper part of the second interlayer insulating film 14 to communicate with the contact holes 14a. Upper interconnects 16 each composed of the upper part of a second barrier metal film 16a and the upper part of a second copper film 16b are formed in the upper interconnect grooves 14b. Plugs 16c each composed of the lower part of the second barrier metal film 16a and the lower part of the second copper film 16b are formed in the contact holes 14a, and the lower interconnect 12 is electrically connected through the plugs 16c to the upper interconnects 16.

The electronic device according to the first embodiment of the present invention is characterized in that the first interlayer insulating film 11 is directly bonded to the second interlayer insulating film 14. Since in this case there exists an interface between the first interlayer insulating film 11 and the second interlayer insulating film 14 which are both hydrophobic, this provides excellent adhesion at the interface between the first interlayer insulating film 11 and the second interlayer insulating film 14. This can prevent the separation between the first interlayer insulating film 11 and the second. interlayer insulating film 14 at the interface therebetween. Therefore, the known problem of the separation between a hydrophobic interlayer insulating film and a hydrophilic barrier film at the interface therebetween can be solved. Furthermore, since a barrier film 13 with a high permittivity is neither formed nor deposited on the first interlayer insulating film 11, this significantly reduces the interconnect capacitance. Therefore, the problem of an interconnect delay for an electronic device can be solved.

FIGS. 2A through 2G are cross-sectional views showing process steps in a fabrication method for an electronic device according to the first embodiment of the present invention.

First, as shown in FIG. 2A, a hydrophobic first interlayer insulating film 11 composed of, for example, a silicon oxide film containing carbon is formed on a silicon substrate (not shown). Thereafter, a cap film (not shown) made of, for example, a silicon oxide film is formed on the first interlayer insulating film 11 (this cap film is to be removed in the later-described step of executing CMP). Subsequently, a resist pattern (not shown) is formed on the cap film to have a pattern for a lower interconnect groove by photolithography, and then the cap film and the first interlayer insulating film 11 are subjected to dry etching using the resist pattern as a mask, thereby forming a lower interconnect groove 11a. Next, a first barrier metal film 12a made of a Ta/TaN multilayer film and a copper seed film (not shown) are successively deposited on the cap film and the first interlayer insulating film 11 by sputtering to fill halfway the lower interconnect groove 11a formed in the cap film and the first interlayer insulating film 11. Subsequently, a first copper film 12b is deposited on the copper seed film by electrolytic plating to completely fill the lower interconnect groove 11a. Subsequently, respective parts of the first barrier metal film 12a and the first copper film 12b located outside the lower interconnect groove 11a and the cap film are removed by CMP (hereinafter, these two films are considered as a multilayer including also the copper seed film interposed therebetween), thereby forming a lower interconnect 12 composed of the first barrier metal film 12a and the first copper film 12b. The lower interconnect 12 has the same configuration as an upper interconnect 16 (see FIG. 2G) formed in the later-described step.

Next, as shown in FIG. 2B, a hydrophilic barrier film 13 functioning as a film for preventing the diffusion of copper and made of, for example, a silicon carbide film is deposited on the lower interconnect 12 and the first interlayer insulating film 11 to have a thickness of approximately 50 nm.

Next, as shown in FIG. 2C, a resist pattern (not shown) is formed on the barrier film 13 by photolithography to mask the lower interconnect 12, and then the barrier film 13 is subjected to dry etching using the resist pattern as a mask. In this way, the barrier film 13 is left only on the lower interconnect 12. Alternatively, a conductive barrier film 13 of, for example, CoWP can be selectively deposited only on the lower interconnect 12, for example, by plasma chemical vapor deposition (p-CVD). Thereafter, as shown in FIG. 2C, a hydrophobic second interlayer insulating film 14 made of, for example, a silicon oxide film containing carbon is deposited on the first interlayer insulating film 11 and the barrier film 13 to have a thickness of approximately 600 nm.

Next, as shown in FIG. 2D, a cap film 15 made of, for example, a silicon oxide film is deposited on the second interlayer insulating film 14 to have a thickness of approximately 50 nm. Subsequently, a resist pattern (not shown) is formed on the cap film 15 by photolithography to have a pattern for contact holes, and then the cap film 15 and the second interlayer insulating film 14 are subjected to dry etching using the resist pattern as a mask. In this way, contact holes 14a are formed to pass through the cap film 15 and the second interlayer insulating film 14 and reach the barrier film 13.

Next, as shown in FIG. 2E, upper interconnect grooves 14b communicating with the contact holes 14a are formed in the upper part of the second interlayer insulating film 14 by opening the cap film 15 and the second insulating film 14 using photolithography and dry etching like the above-described method for forming the contact holes 14a.

Next, as shown in FIG. 2F, the substrate is entirely etched-back by dry etching using a mixed gas of, for example, CF₄ and N₂, thereby removing parts of the barrier film 13 exposed at the bottoms of the contact holes 14a to partly expose the lower interconnect 12.

Next, as shown in FIG. 2G, a second barrier metal film 16a made of a Ta/TaN multilayer film and a copper seed film (not shown) are successively deposited on the second interlayer insulating film 14 by sputtering to fill halfway each contact hole 14a and the associated upper interconnect groove 14b. Subsequently, a second copper film 16b is deposited on the copper seed film by electrolytic plating to completely fill the contact hole 14a and the upper interconnect groove 14b. Next, respective parts of the cap film 15, the second barrier metal film 16a and the second copper film 16b located outside the upper interconnect groove 104b are removed by CMP (hereinafter, these two films are considered as a multilayer including also the copper seed film interposed therebetween). In this way, upper interconnects 16 are formed, each composed of an upper part of a second barrier metal film 16a and an upper part of a second copper film 16b. Plugs 16c each composed of a lower part of a second barrier metal film 16a and a lower part of a second copper film 16b are formed in the contact holes 14a, respectively, and the lower interconnect 12 is electrically connected through the plugs 16c to the upper interconnects 16. The second barrier metal film 16a formed on the bottom and side surfaces of the second copper film 16b with which a contact hole 14a and an upper interconnect groove 14b are filled functions as a film for preventing the diffusion of copper.

The above-described fabrication process steps, i.e., the process steps in the method for fabricating an electronic device as shown in FIGS. 2A through 2G are repeated, thereby obtaining an electronic device of the first embodiment having a multilayer copper interconnect.

The fabrication method for an electronic device according to the first embodiment of the present invention is characterized in that the first and second interlayer insulating films 11 and 14 are formed so as to be directly bonded to each other. Since in this case there exists an interface between the first interlayer insulating film 11 and the second interlayer insulating film 14 which are both hydrophobic, this provides excellent adhesion at the interface between the first interlayer insulating film 11 and the second interlayer insulating film 14. This can prevent the separation between the first interlayer insulating film 11 and the second interlayer insulating film 14 at the interface therebetween. Therefore, the known problem of the separation between a hydrophobic interlayer insulating film and a hydrophilic barrier film at the interface therebetween can be solved. Furthermore, since a barrier film 13 with a high permittivity is neither formed nor deposited on the first interlayer insulating film 11, this significantly reduces the interconnect capacitance. Therefore, the problem of an interconnect delay for an electronic device can be solved.

Although a description was given above of the case where the first and second interlayer insulating films 11 and 14 are both hydrophobic, a hydrophilic material, such as nanoporous-silica-based material (for example, nano clustering silica (NCS)), may be used as a material used for both the first and second interlayer insulating films 11 and 14 in this embodiment. Since as described above the first and second interlayer insulating films 11 and 14 are both hydrophilic, this can improve the adhesion between the first and second interlayer insulating films 11 and 14, leading to the prevention of the separation therebetween at their interface.

Furthermore, the first and second interlayer insulating films 11 and 14 are preferably made of a film having a low permittivity of 2.4 or less to reduce the electrical parasitic capacitances between interconnects.

Although a description was given above of the case where copper is used as a material for interconnects (the lower interconnect 12 and the upper interconnects 16), the type of the material for interconnects is not particularly limited in this embodiment. For example, copper, silver, aluminum, or their alloys may be used.

Moreover, in this embodiment, the length obtained by summing the width of the lower interconnect 12 and the distance between the lower interconnect 12 and an interconnect adjacent to the lower interconnect 12 is preferably 0.4 μm.

Although a description was given above of the case where the Ta/TaN multilayer film is used for the barrier metal films (the first barrier metal film 12a and the second barrier metal film 16a), the type of the barrier metal films is not particularly limited in this embodiment. For example, a Ta film, a TaN film, a WN film, a TiN film, or their multilayer film may be used.

Although a description was given above of the case where a silicon carbide film (SiC film) is used for the barrier film 13, the type of the barrier film 13 is not particularly limited in this embodiment. An insulative barrier film made of any one selected from the group of, for example, a SiN film (silicon nitride film), a SiCN film (silicon carbide nitride film), a SiC film, a SiCH film, and a BCB film (benzocyclobutene film) or a conductive barrier film made of any one selected from the group of, for example, a CoWP film and a CoWB (cobalt tungsten boride) film can be used for the barrier film 13.

Although a description was given above of the case where a first barrier metal film 12a is formed over the side and bottom surfaces of the lower interconnect 12, a first barrier metal film 12a does not have to be formed in the lower interconnect groove 11a in this embodiment. Even in this case, not only when a material other than the above-described copper is used as a material for a lower interconnect but also when copper that is likely to diffuse into interlayer insulating films is used thereas, the reduced interconnect resistance can be achieved as compared with the known structure of an electronic device in which a barrier film is interposed between first and second interlayer insulating films, and the known problem of the separation between films at their interface can be solved.

### Embodiment 2

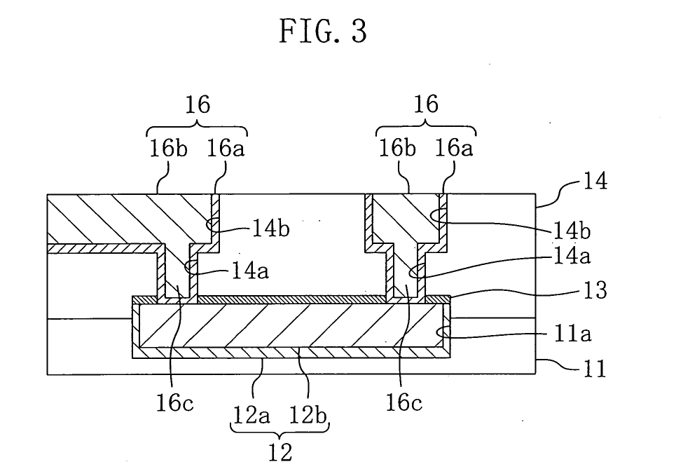

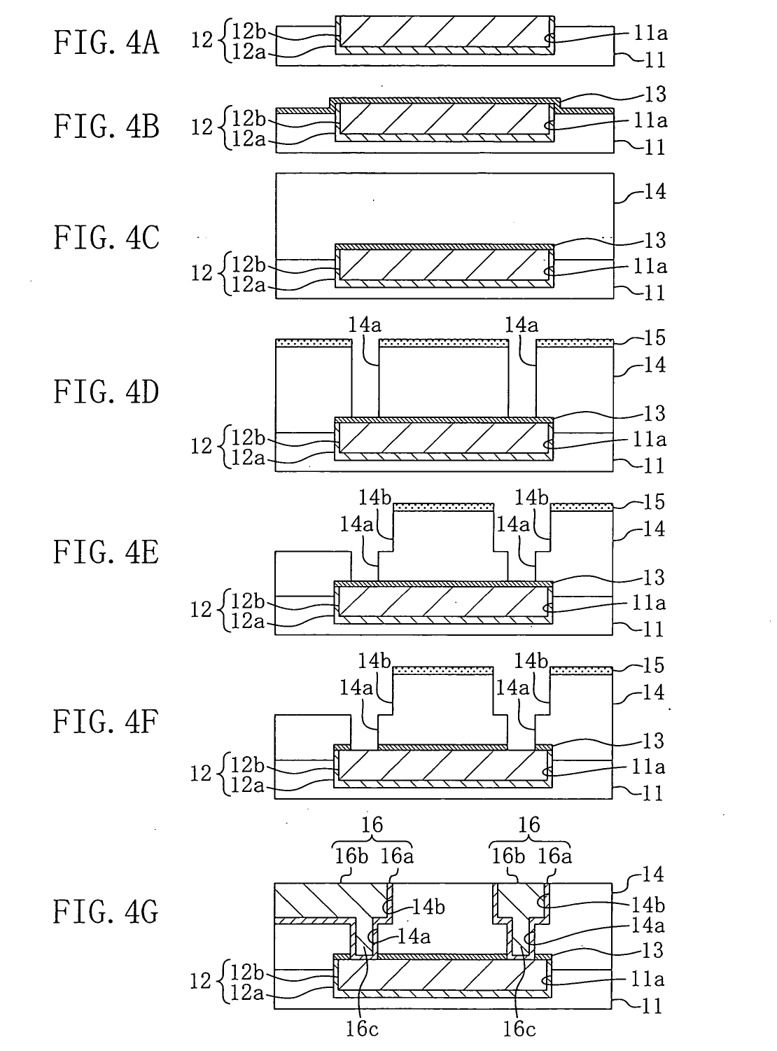

An electronic device according to a second embodiment of the present invention and a fabrication method for the same will be described hereinafter with reference to FIGS. 3 and 4A through 4G.

FIG. 3 is a cross-sectional view showing the structure of an electronic device according to the second embodiment of the present invention.

As shown in FIG. 3, a hydrophobic first interlayer insulating film 11 and a hydrophobic second interlayer insulating film 14 are successively formed on a silicon substrate (not shown). A lower interconnect 12 obtained by stacking a first barrier metal film 12a and a first copper film 12b in this order is formed in a lower interconnect groove 11a formed in the first and second interlayer insulating film 11 and 14. A hydrophilic barrier film 13 functioning as a film for preventing the diffusion of copper or a conductive barrier film 13 made of, for example, CoWP (cobalt tungsten phosphide) is formed on the lower interconnect 12.

The second interlayer insulating film 14 is formed over the first interlayer insulating film 11 and the barrier film 13. Contact holes 14a are formed in the lower part of the second interlayer insulating film 14 and the barrier film 13 to partly expose the top surface of the lower interconnect 12. In addition, upper interconnect grooves 14b are formed in the upper part of the second interlayer insulating film 14 to communicate with the contact holes 14a. Upper interconnects 16 each composed of the upper part of a second barrier metal film 16a and the upper part of a second copper film 16b are formed in the upper interconnect grooves 14b. Plugs 16c each composed of the lower part of the second barrier metal film 16a and the lower part of the second copper film 16b are formed in the contact holes 14a, and the lower interconnect 12 is electrically connected through the plugs 16c to the upper interconnects 16.

The electronic device according to the second embodiment of the present invention is characterized in that the first interlayer insulating film 11 is directly bonded to the second interlayer insulating film 14 and the interface at which the first and second interlayer insulating films 11 and 14 are bonded to each other is located below the top surface of the lower interconnect 12. Since in this case there exists an interface between the first interlayer insulating film 11 and the second interlayer insulating film 14 that are both hydrophobic, this provides excellent adhesion at the interface between the first interlayer insulating film 11 and the second interlayer insulating film 14. This can prevent the separation between the first interlayer insulating film 11 and the second interlayer insulating film 14 at the interface therebetween. Therefore, the known problem of the separation between a hydrophobic interlayer insulating film and a hydrophilic barrier film at the interface therebetween can be solved. Moreover, since the interface at which the first and second interlayer insulating films 11 and 14 are bonded to each other, though serving as a path through which copper is likely to diffuse into the interlayer insulating films, is located below the top surface of the lower interconnect 12, copper can be restrained from diffusing from the lower interconnect 12 into the interlayer insulating films. This can improve the reliability of the copper interconnect. Furthermore, since a barrier film 13 with a high permittivity is neither formed nor deposited on the first interlayer insulating film 11, this significantly reduces the interconnect capacitance. Therefore, the problem of an interconnect delay for an electronic device can be solved. Furthermore, when the height of the lower interconnect 12 is 250 nm or less, the interface at which the first and second interlayer insulating films 11 and 14 are bonded to each other is preferably located 10 nm or more below the top surface of the lower interconnect 12.

FIGS. 4A through 4G are cross-sectional views showing process steps in a fabrication method for an electronic device according to the second embodiment of the present invention. The process steps shown in FIGS. 4B through 4G are similar to those shown in FIGS. 2B through 2G in the first embodiment. Therefore, a description of the process steps shown in FIGS. 4B through 4G is not given in this embodiment. A description will be given below of the characteristic of the fabrication method for an electronic device according to the second embodiment of the present invention, i.e., the process steps shown in FIG. 4A including process step for forming first and second interlayer insulating films 11 and 14 such that the interface at which they are bonded to each other is located below the top surface of the lower interconnect 12.

First, as shown in FIG. 4A, a hydrophobic first interlayer insulating film 11 composed of, for example, a silicon oxide film containing carbon is formed on a silicon substrate (not shown). Thereafter, a cap film (not shown) made of, for example, a silicon oxide film is formed on the first interlayer insulating film 11 (this cap film is to be removed in the later-described step of executing CMP). Subsequently, a resist pattern (not shown) is formed on the cap film to have a pattern for a lower interconnect groove by photolithography, and then the cap film and the first interlayer insulating film 11 are subjected to dry etching using the resist pattern as a mask, thereby forming a lower interconnect groove 11a. Next, a first barrier metal film 12a made of a Ta/TaN multilayer film and a copper seed film (not shown) are successively deposited on the cap film and the first interlayer insulating film 11 by sputtering to fill halfway the lower interconnect groove 11a formed in the cap film and the first interlayer insulating film 11. Subsequently, a first copper film 12b is deposited on the copper seed film by electrolytic plating to completely fill the lower interconnect groove 11a. Subsequently, respective parts of the first barrier metal film 12a and the first copper film 12b located outside the lower interconnect groove 11a and the cap film are removed by CMP (hereinafter, these two films are considered as a multilayer including also the copper seed film interposed therebetween), thereby forming a lower interconnect 12 composed of the first barrier metal film 12a and the first copper film 12b.

The above-described process step is identical with that in the fabrication method for an electronic device according to the first embodiment of the present invention. In the fabrication method for an electronic device according to the second embodiment of the present invention, the following process step is further carried out. The exposed top surface of the first interlayer insulating film 11 is reformed, for example, by a plasma process using a NH₃ gas, and then the reformed top surface of the first interlayer insulating film 11 is removed, for example, using a chemical solution, such as HF (hydrofluoric acid). Alternatively, the top surface of the first interlayer insulating film 11 may be selectively removed by CMP. In this case, a slurry is used which allows an insulating film to be selectively removed more easily than an interconnect material. In this embodiment, an interconnect is composed of Cu (copper) and Ta (tantalum), and an insulating film is composed of SiOC (silicon oxycarbide). Therefore, a slurry is used which allows SiOC to be selectively removed more easily than Cu and Ta. In this way, as shown in FIG. 4A, the exposed top surface of the first interlayer insulating film 11 is located below the top surface of the lower interconnect 12. As a result, in a later process step, a second interlayer insulating film 14 is formed so as to be bonded to the first interlayer insulating film 11, and therefore the interface between the first and second interlayer insulating films 11 and 14 can be located below the top surface of the lower interconnect 12. To be specific, when the height of the lower interconnect 12 is 250 nm or less, the interface at which the first and second interlayer insulating films 11 and 14 are bonded to each other is preferably located 10 nm or more below the top surface of the lower interconnect 12.

The fabrication method for an electronic device according to the second embodiment of the present invention is characterized in that the first interlayer insulating film 11 is directly jointed to the second interlayer insulating film 14 and the interface at which the first and second interlayer insulating films 11 and 14 are bonded to each other is located below the top surface of the lower interconnect 12. Since in this case there exists an interface between the first interlayer insulating film 11 and the second interlayer insulating film 14 that are both hydrophobic, this provides excellent adhesion at the interface between the first interlayer insulating film 11 and the second interlayer insulating film 14. This can prevent the separation between the first interlayer insulating film 11 and the second interlayer insulating film 14 at the interface therebetween. Therefore, the known problem of the separation between a hydrophobic interlayer insulating film and a hydrophilic barrier film at the interface therebetween can be solved. Moreover, since the interface at which the first and second interlayer insulating films 11 and 14 are bonded to each other, though serving as a path through which copper is likely to diffuse into the interlayer insulating films, is located below the top surface of the lower interconnect 12, copper can be restrained from diffusing from the lower interconnect 12 into the interlayer insulating films. This can improve the reliability of the copper interconnect. Furthermore, since a barrier film 13 with a high permittivity is neither formed nor deposited on the first interlayer insulating film 11, this significantly reduces the interconnect capacitance. Therefore, the problem of an interconnect delay for an electronic device can be solved.

Although a description was given above of the case where the first and second interlayer insulating films 11 and 14 are both hydrophobic, a hydrophilic material, such as nanoporous-silica-based material (for example, nano clustering silica (NCS)), may be used as a material used for both the first and second interlayer insulating films 11 and 14 in this embodiment. Since as described above the first and second interlayer insulating films 11 and 14 are both hydrophilic, this can improve the adhesion between the first and second interlayer insulating films 11 and 14, leading to the prevention of the separation therebetween at their interface.

Furthermore, the first and second interlayer insulating films 11 and 14 are preferably made of a film having a low permittivity of 2.4 or less to reduce the electrical parasitic capacitances between interconnects.

Although a description was given above of the case where copper is used as a material for interconnects (the lower interconnect 12 and the upper interconnect 16), the type of the material for interconnects is not particularly limited in this embodiment. For example, copper, silver, aluminum, or their alloys may be used.

Moreover, in this embodiment, the length obtained by summing the width of the lower interconnect 12 and the distance between the lower interconnect 12 and an interconnect adjacent to the lower interconnect 12 is preferably 0.4 μm.

Although a description was given above of the case where the Ta/TaN multilayer film is used for the barrier metal films (the first barrier metal film 12a and the second barrier metal film 16a), the type of the barrier metal films is not particularly limited in this embodiment. For example, a Ta film, a TaN film, a WN film, a TiN film, or their multilayer film may be used.

Although a description was given above of the case where a silicon carbide film (SiC film) is used for the barrier film 13, the type of the barrier film 13 is not particularly limited in this embodiment. An insulative barrier film made of any one selected from the group of, for example, a SiN film (silicon nitride film), a SiCN film (silicon carbide nitride film), a SiC film, a SiCH film, and a BCB film (benzocyclobutene film) or a conductive barrier film made of any one selected from the group of, for example, a CoWP film and a CoWB (cobalt tungsten boride) film can be used for the barrier film 13.

Although a description was given above of the case where a first barrier metal film 12a is formed over the side and bottom surfaces of the lower interconnect 12, a first barrier metal film 12a does not have to be formed in the lower interconnect groove 11a in this embodiment. Even in this case, not only when a material other than the above-described copper is used as a material for a lower interconnect but also when copper that is likely to diffuse into interlayer insulating films is used thereas, the reduced interconnect resistance can be achieved as compared with the known structure of an electronic device in which a barrier film is interposed between first and second interlayer insulating films, and the known problem of the separation between films at their interface can be solved.

### Embodiment 3

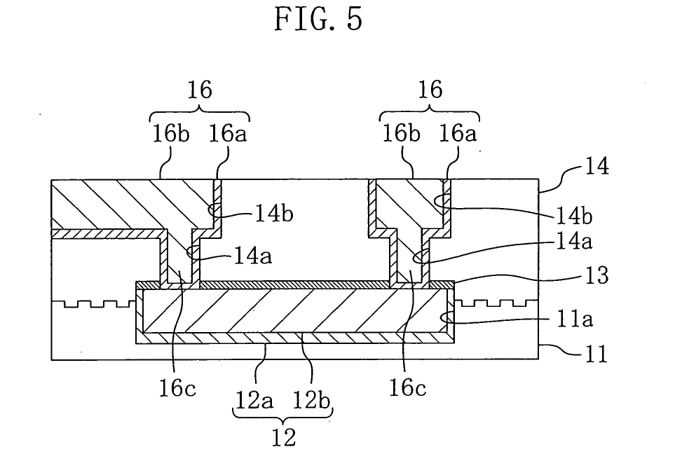

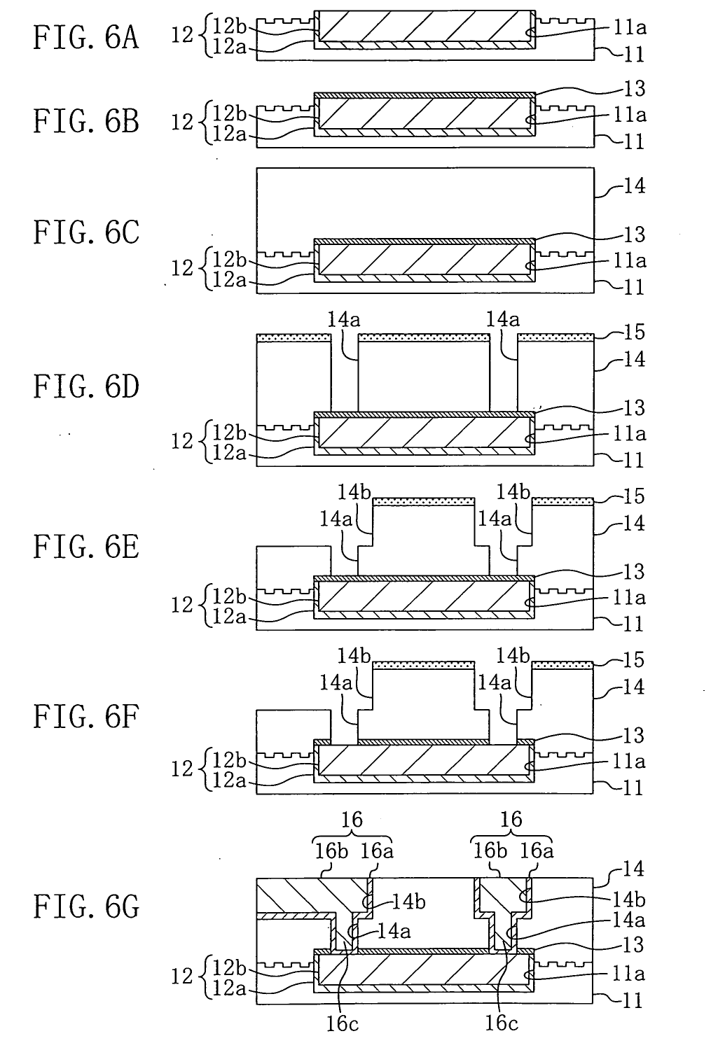

An electronic device according to a third embodiment of the present invention and a fabrication method for the same will be described hereinafter with reference to FIGS. 5 and 6A through 6G.

FIG. 5 is a cross-sectional view showing the structure of an electronic device according to the third embodiment of the present invention.

As shown in FIG. 5, a hydrophobic first interlayer insulating film 11 and a hydrophobic second interlayer insulating film 14 are successively formed on a silicon substrate (not shown). A lower interconnect 12 obtained by stacking a first barrier metal film 12a and a first copper film 12b in this order is formed in a lower interconnect groove 11a formed in the first and second interlayer insulating film 11 and 14. A hydrophilic barrier film 13 functioning as a film for preventing the diffusion of copper or a conductive barrier film 13 made of, for example, CoWP (cobalt tungsten phosphide) is formed on the lower interconnect 12. The second interlayer insulating film 14 is formed over the first interlayer insulating film 11 and the barrier film 13.

In this relation, the first and second interlayer insulating films 11 and 14 are directly bonded to each other, and the interface at which the first and second interlayer insulating films 11 and 14 are bonded to each other is located below the top surface of the lower interconnect 12. Furthermore, the interface at which the first and second interlayer insulating films 11 and 14 are bonded to each other is uneven. It is preferable that for the surface roughness of the interface at which the first and second interlayer insulating films 11 and 14 are bonded to each other, the arithmetic average roughness Rₐ thereof is 4 nm or less or the maximum height Rₘₐₓ thereof is 50 nm or less. As seen from the above, the interface between the first and second interlayer insulating films 11 and 14 is formed to have greater roughness than a normal interface. This can improve the adhesion at the interface therebetween and restrain copper from diffusing into the interlayer insulating films. The arithmetic average roughness Rₐ and the maximum height Rₘₐₓ are kinds of indices defining the surface roughness. The arithmetic average roughness Rₐ represents an average of absolute roughness values with respect to the mean line of a profile showing variation in the level of the interface. The maximum height Rₘₐₓ represents the difference in level between the highest point and lowest point of the above-described profile with respect to the mean line within a sampling interface length.

Contact holes 14a are formed in the lower part of the second interlayer insulating film 14 and the barrier film 13 to partly expose the top surface of the lower interconnect 12. In addition, upper interconnect grooves 14b are formed in the upper part of the second interlayer insulating film 14 to communicate with the contact holes 14a. Upper interconnects 16 each composed of the upper part of a second barrier metal film 16a and the upper part of a second copper film 16b are formed in the upper interconnect grooves 14b. Plugs 16c each composed of the lower part of the second barrier metal film 16a and the lower part of the second copper film 16b are formed in the contact holes 14a, and the lower interconnect 12 is electrically connected through the plugs 16c to the upper interconnects 16.

The electronic device according to the third embodiment of the present invention is characterized as follows: the first interlayer insulating film 11 is directly bonded to the second interlayer insulating film 14; the interface at which the first and second interlayer insulating films 11 and 14 are bonded to each other is located below the top surface of the lower interconnect 12; and, in addition, the interface at which the first and second interlayer insulating films 11 and 14 are bonded to each other is uneven. Since in this case there exists an interface between the first interlayer insulating film 11 and the second interlayer insulating film 14 that are both hydrophobic, this provides excellent adhesion at the interface between the first interlayer insulating film 11 and the second interlayer insulating film 14. This can prevent the separation between the first interlayer insulating film 11 and the second interlayer insulating film 14 at the interface therebetween. Therefore, the known problem of the separation between a hydrophobic interlayer insulating film and a hydrophilic barrier film at the interface therebetween can be solved. Moreover, since the interface at which the first and second interlayer insulating films 11 and 14 are bonded to each other, though serving as a path through which copper is likely to diffuse into the interlayer insulating films, is located below the top surface of the lower interconnect 12, copper can be restrained from diffusing from the lower interconnect 12 into the interlayer insulating films. Moreover, since the interface at which the first and second interlayer insulating films 11 and 14 are bonded to each other is uneven, this increases the area in which the first interlayer insulating film 11 comes into contact with the second interlayer insulating film 14 at their interface. Therefore, the adhesion at their interface is sharply improved. In addition, copper can be restrained from diffusing into the interlayer insulating films because of the increased length of the interface between the first and second interlayer insulating films 11 and 14, which serves as a path through which copper diffuses into the interlayer insulating films, i.e., the increased distance over which copper diffuses. This can improve the reliability of the copper interconnect. Furthermore, since a barrier film 13 with a high permittivity is neither formed nor deposited on the first interlayer insulating film 11, this significantly reduces the interconnect capacitance. Therefore, the problem of an interconnect delay for an electronic device can be solved. Furthermore, when the height of the lower interconnect 12 is 250 nm or less, the interface at which the first and second interlayer insulating films 11 and 14 are bonded to each other is preferably located 10 nm or more below the top surface of the lower interconnect 12.

FIGS. 6A through 6G are cross-sectional views showing process steps in a fabrication method for an electronic device according to the third embodiment of the present invention. The process steps shown in FIGS. 6B through 6G are similar to those shown in FIGS. 2B through 2G in the first embodiment. Therefore, a description of the process steps shown in FIGS. 6B through 6G is not given in this embodiment. A description will be given below of the characteristic of the fabrication method for an electronic device according to the third embodiment of the present invention, i.e., the process step shown in FIG. 6A including a process step for forming first and second interlayer insulating films 11 and 14 such that the interface at which they are bonded to each other is uneven.

First, as shown in FIG. 6A, a hydrophobic first interlayer insulating film 11 composed of, for example, a silicon oxide film containing carbon is formed on a silicon substrate (not shown). Thereafter, a cap film (not shown) made of, for example, a silicon oxide film is formed on the first interlayer insulating film 11 (this cap film is to be removed in the later-described step of carrying out CMP). Subsequently, a resist pattern (not shown) is formed on the cap film to have a pattern for a lower interconnect groove by photolithography, and then the cap film and the first interlayer insulating film 11 are subjected to dry etching using the resist pattern as a mask, thereby forming a lower interconnect groove 11a. Next, a first barrier metal film 12a made of a Ta/TaN multilayer film and a copper seed film (not shown) are successively deposited on the cap film and the first interlayer insulating film 11 by sputtering to fill halfway the lower interconnect groove 11a formed in the cap film and the first interlayer insulating film 11. Subsequently, a first copper film 12b is deposited on the copper seed film by electrolytic plating to completely fill the lower interconnect groove 11a. Subsequently, respective parts of the first barrier metal film 12a and the first copper film 12b located outside the lower interconnect groove 11a and the cap film are removed by CMP (hereinafter, these two films are considered as a multilayer including also the copper seed film interposed therebetween), thereby forming a lower interconnect 12 composed of the first barrier metal film 12a and the first copper film 12b.

The above-described process step is identical with that in the fabrication method for an electronic device according to the first embodiment of the present invention. In the third embodiment of the present invention, the density of abrasive grains in CMP slurry is set at 20 wt % or more in CMP used for the formation of the lower interconnect 12. In this way, the exposed top surface of the first insulating film 11 can be located below the top surface of the lower interconnect 12 and formed to become uneven. Alternatively, after the formation of the lower interconnect 12 by CMP as described above, an uneven reformed layer is formed in the exposed top surface of the first interlayer insulating film 11 by a plasma process using a mixed gas of a gas having molecules of high mass number and a gas having molecules of low mass number, such as a mixed gas of Ar and H₂. Subsequently, the uneven reformed layer is removed by a chemical solution, such as HF. In this way, the exposed top surface of the first interlayer insulating film 11 can be located below the top surface of the lower interconnect 12 and formed to become uneven. As described above, it is preferable that for the surface roughness of the interface at which the first and second interlayer insulating films 11 and 14 are bonded to each other, the arithmetic average roughness Rₐ thereof is 4 nm or less or the maximum height Rₘₐₓ thereof is 50 nm or less.

The fabrication method for an electronic device according to the third embodiment of the present invention is characterized as follows: the first interlayer insulating film 11 is directly bonded to the second interlayer insulating film 14; the interface at which the first and second interlayer insulating films 11 and 14 are bonded to each other is located below the top surface of the lower interconnect 12; and, in addition, the interface at which the first and second interlayer insulating films 11 and 14 are bonded to each other is uneven. Since in this case there exists an interface between the first interlayer insulating film 11 and the second interlayer insulating film 14 that are both hydrophobic, this provides excellent adhesion at the interface between the first interlayer insulating film 11 and the second interlayer insulating film 14. This can prevent the separation between the first interlayer insulating film 11 and the second interlayer insulating film 14 at the interface therebetween. Therefore, the known problem of the separation between a hydrophobic interlayer insulating film and a hydrophilic barrier film at the interface therebetween can be solved. Moreover, since the interface at which the first and second interlayer insulating films 11 and 14 are bonded to each other, though serving as a path through which copper is likely to diffuse into the interlayer insulating films, is located below the top surface of the lower interconnect 12, copper can be restrained from diffusing from the lower interconnect 12 into the interlayer insulating films. Moreover, since the interface at which the first and second interlayer insulating films 11 and 14 are bonded to each other is uneven, this increases the area in which the first interlayer insulating film 11 comes into contact with the second interlayer insulating film 14 at their interface. Therefore, the adhesion at their interface is sharply improved. In addition, copper can be restrained from diffusing into the interlayer insulating films because of the increased length of the interface between the first and second interlayer insulating films 11 and 14, which serves as a path through which copper diffuses into the interlayer insulating films, i.e., the increased distance over which copper diffuses. This can improve the reliability of the copper interconnect. Furthermore, since a barrier film 13 with a high permittivity is neither formed nor deposited on the first interlayer insulating film 11, this significantly reduces the interconnect capacitance. Therefore, the problem of an interconnect delay for an electronic device can be solved. Furthermore, when the height of the lower interconnect 12 is 250 nm or less, the interface at which the first and second interlayer insulating films 11 and 14 are bonded to each other is preferably located 10 nm or more below the top surface of the lower interconnect 12.

Although a description was given above of the case where the first and second interlayer insulating films 11 and 14 are both hydrophobic, a hydrophilic material, such as nanoporous-silica-based material (for example, nano clustering silica (NCS)), may be used as a material used for both the first and second interlayer insulating films 11 and 14 in this embodiment. Since as described above the first and second interlayer insulating films 11 and 14 are both hydrophilic, this can improve the adhesion between the first and second interlayer insulating films 11 and 14, leading to the prevention of the separation therebetween at their interface.

Furthermore, the first and second interlayer insulating films 11 and 14 are preferably made of a film having a low permittivity of 2.4 or less to reduce the electrical parasitic capacitances between interconnects.

Although a description was given above of the case where copper is used as a material for interconnects (the lower interconnect 12 and the upper interconnect 16), the type of the material for interconnects is not particularly limited in this embodiment. For example, copper, silver, aluminum, or their alloys may be used.

Moreover, in this embodiment, the length obtained by summing the width of the lower interconnect 12 and the distance between the lower interconnect 12 and an interconnect adjacent to the lower interconnect 12 is preferably 0.4 μm.

Although a description was given above of the case where the Ta/TaN multilayer film is used for the barrier metal films (the first barrier metal film 12a and the second barrier metal film 16a), the type of the barrier metal films is not particularly limited in this embodiment. For example, a Ta film, a TaN film, a WN film, a TiN film, or their multilayer film may be used.

Although a description was given above of the case where a silicon carbide film (SiC film) is used for the barrier film 13, the type of the barrier film 13 is not particularly limited in this embodiment. An insulative barrier film made of any one selected from the group of, for example, a SiN film (silicon nitride film), a SiCN film (silicon carbide nitride film), a SiC film, a SiCH film, and a BCB film (benzocyclobutene film) or a conductive barrier film made of any one selected from the group of, for example, a CoWP film and a CoWB (cobalt tungsten boride) film can be used for the barrier film 13.

Although a description was given above of the case where a first barrier metal film 12a is formed over the side and bottom surfaces of the lower interconnect 12, a first barrier metal film 12a does not have to be formed in the lower interconnect groove 11a in this embodiment. Even in this case, not only when a material other than the above-described copper is used as a material for a lower interconnect but also when copper that is likely to diffuse into interlayer insulating films is used thereas, the reduced interconnect resistance can be achieved as compared with the known structure of an electronic device in which a barrier film is interposed between first and second interlayer insulating films, and the known problem of the separation between films at their interface can be solved.

Although a description was given above of the case where a plasma made of a mixed gas of Ar and H₂ is used to form an uneven reformed layer in the exposed top surface of the first interlayer insulating film, a mixed gas of Ar and He, a mixed gas of NH₃ and He, a mixed gas of NH₃ and H₂, or the like may be used.

Moreover, a description was given above of the case where the exposed top surface of the first interlayer insulating film 11 is located below the top surface of the lower interconnect 12 and formed to become uneven. However, the exposed top surface of the first interlayer insulating film 11 may be formed to become uneven without being located below the top surface of the lower interconnect 12. Since also in this case the uneven exposed top surface of the first interlayer insulating film 11 increases the area in which the first and second interlayer insulating films 11 and 14 come into contact with each other, this improves the adhesion at the interface between the first and second interlayer insulating films 11 and 14. In addition, since the uneven exposed top surface of the first interlayer insulating film 11 increases the length of the path through which copper diffuses into the interlayer insulating films, this can restrain copper from diffusing over a broad range of the interface.

The method used in the second embodiment may be used to locate the exposed top surface of the first interlayer insulating film 11 below the top surface of the lower interconnect 12. Thereafter, the exposed top surface of the first interlayer insulating film 11 may be formed using the above-described method to become uneven. To be specific, the exposed top surface of the first interlayer insulating film 11 formed on the substrate is reformed by a plasma process using a NH₃ gas, and then the reformed top surface of the first interlayer insulating film 11 is removed, for example, using a chemical solution, such as HF. Alternatively, the top surface of the first interlayer insulating film 11 may be selectively removed by CMP using a slurry that facilitates selectively removing an insulating film. In this way, the exposed top surface of the first interlayer insulating film 11 is located below the top surface of the lower interconnect 12. Subsequently, the density of abrasive grains in CMP slurry is set at 20 wt % or more. In this way, the exposed top surface of the first insulating film 11 can be reformed to become uneven. Alternatively, an uneven reformed layer is formed in the exposed top surface of the first interlayer insulating film 11 by a plasma process using a mixed gas of a gas having molecules of high mass number and a gas having molecules of low mass number, such as a mixed gas of Ar and H₂.

### Embodiment 4

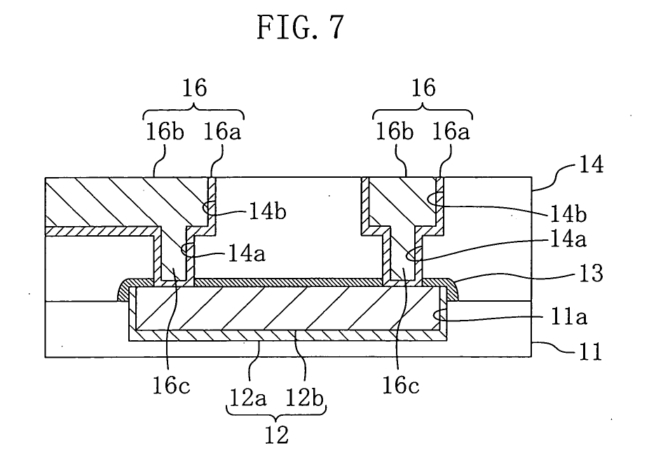

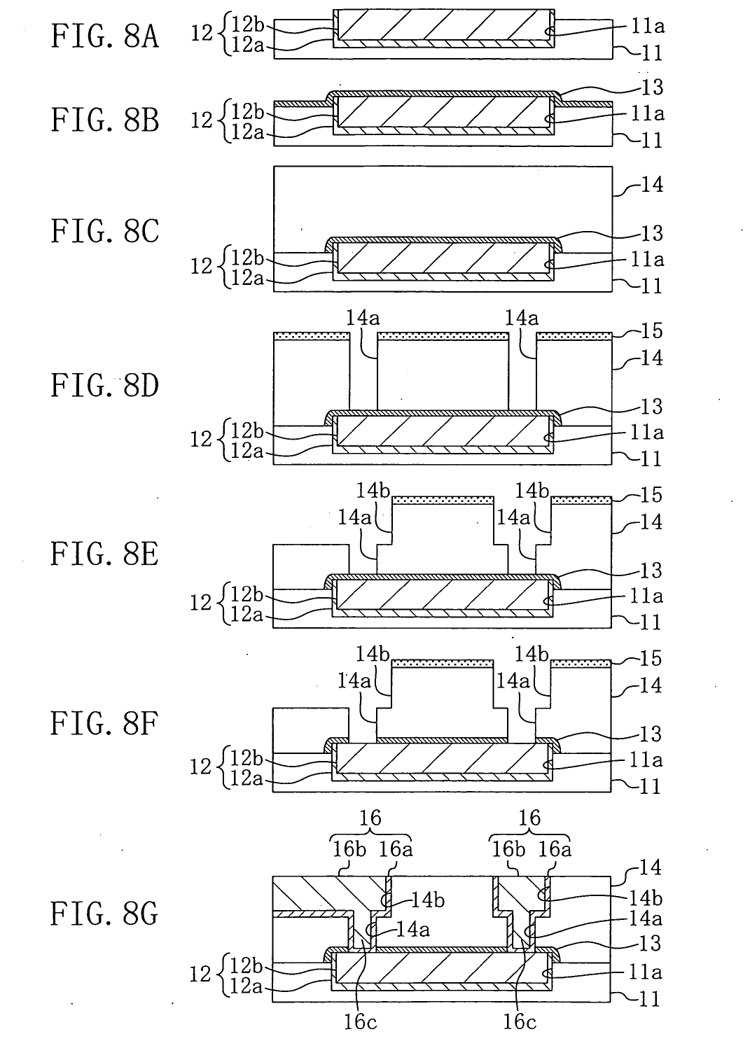

An electronic device according to a fourth embodiment of the present invention and a fabrication method for the same will be described hereinafter with reference to FIGS. 7 and 8A through 8G.

FIG. 7 is a cross-sectional view showing the structure of an electronic device according to the fourth embodiment of the present invention.

As shown in FIG. 7, a hydrophobic first interlayer insulating film 11 and a hydrophobic second interlayer insulating film 14 are successively formed on a silicon substrate (not shown). A lower interconnect 12 obtained by stacking a first barrier metal film 12a and a first copper film 12b in this order is formed in a lower interconnect groove 11a formed in the first and second interlayer insulating film 11 and 14. A hydrophilic barrier film 13 functioning as a film for preventing the diffusion of copper or a conductive barrier film 13 made of, for example, CoWP (cobalt tungsten phosphide) is formed on the top and side surfaces of the lower interconnect 12. The second interlayer insulating film 14 is formed over the first interlayer insulating film 11 and the barrier film 13.

In this relation, the first and second interlayer insulating films 11 and 14 are directly bonded to each other, and the interface at which the first and second interlayer insulating films 11 and 14 are bonded to each other is located below the top surface of the lower interconnect 12. Furthermore, the barrier film 13 partly has a sidewall on the side surface of the lower interconnect 12.

Contact holes 14a are formed in the lower part of the second interlayer insulating film 14 and the barrier film 13 to partly expose the top surface of the lower interconnect 12. In addition, upper interconnect grooves 14b are formed in the upper part of the second interlayer insulating film 14 to communicate with the contact holes 14a. Upper interconnects 16 each composed of the upper part of a second barrier metal film 16a and the upper part of a second copper film 16b are formed in the contact holes 14a and the upper interconnect grooves 14b. Plugs 16c each composed of the lower part of the second barrier metal film 16a and the lower part of the second copper film 16b are formed in the contact holes 14a, and the lower interconnect 12 is electrically connected through the plugs 16c to the upper interconnects 16.

The electronic device according to the fourth embodiment of the present invention is characterized as follows: the first interlayer insulating film 11 is directly bonded to the second interlayer insulating film 14; the interface at which the first and second interlayer insulating films 11 and 14 are bonded to each other is located below the top surface of the lower interconnect 12; and, in addition, the barrier film 13 partly has a sidewall on the side surface of the lower interconnect 12. Since in this case there exists an interface between the first interlayer insulating film 11 and the second interlayer insulating film 14 that are both hydrophobic, this provides excellent adhesion at the interface between the first interlayer insulating film 11 and the second interlayer insulating film 14. This can prevent the separation between the first interlayer insulating film 11 and the second interlayer insulating film 14 at the interface therebetween. Therefore, the known problem of the separation between a hydrophobic interlayer insulating film and a hydrophilic barrier film at the interface therebetween can be solved. Moreover, since the interface at which the first and second interlayer insulating films 11 and 14 are bonded to each other, though serving as a path through which copper is likely to diffuse into the interlayer insulating films, is located below the top surface of the lower interconnect 12, copper can be restrained from diffusing from the lower interconnect 12 into the interlayer insulating films. Furthermore, since part of a barrier film 13 forms a sidewall on the side surface of the lower interconnect 12, this increases the length of the interface at which copper diffuses from the lower interconnect 12 into the interlayer insulating films. Therefore, copper can be restrained from diffusing from the lower interconnect 12 into the interlayer insulating films. More particularly, since the interface between the lower interconnect 12 and the second interlayer insulating film 14, at which copper diffuses from the lower interconnect 12 into the interlayer insulating films, is completely covered with part of the barrier film 13 serving as a sidewall, this increases the energy gap beyond which copper atoms should go to diffuse into the interlayer insulating films. Therefore, copper can be restrained from diffusing from the lower interconnect 12 into the interlayer insulating films. This can improve the reliability of the copper interconnect. Furthermore, since a barrier film 13 with a high permittivity is neither formed nor deposited on the first interlayer insulating film 11, this significantly reduces the interconnect capacitance. Therefore, the problem of an interconnect delay for an electronic device can be solved.

Furthermore, in this embodiment, when the height of the lower interconnect 12 is 250 nm or less, the interface at which the first and second interlayer insulating films 11 and 14 are bonded to each other is preferably located 10 nm or more below the top surface of the lower interconnect 12.

FIGS. 8A through 8G are cross-sectional views showing process steps in a fabrication method for an electronic device according to the fourth embodiment of the present invention. The process steps shown in FIGS. 8D through 8G are similar to those shown in FIGS. 2D through 2G in the first embodiment. Therefore, a description of the process steps shown in FIGS. 8D through 8G is not given in this embodiment. A description will be given below of the characteristic of the fabrication method for an electronic device according to the fourth embodiment of the present invention, i.e., the process steps shown in FIG. 8A through 8C including the process step for forming first and second interlayer insulating films 11 and 14 such that the interface at which they are bonded to each other is located below the top surface of a lower interconnect 12 and forming a barrier film 13 such that part of the barrier film 13 located on the side surface of the lower interconnect 12 forms a sidewall shape.

First, as shown in FIG. 8A, a hydrophobic first interlayer insulating film 11 composed of, for example, a silicon oxide film containing carbon is formed on a silicon substrate (not shown). Thereafter, a cap film (not shown) made of, for example, a silicon oxide film is formed on the first interlayer insulating film 11 (this cap film is to be removed in the later-described step of executing CMP). Subsequently, a resist pattern (not shown) is formed on the cap film to have a pattern for a lower interconnect groove by photolithography, and then the cap film and the first interlayer insulating film 11 are subjected to dry etching using the resist pattern as a mask, thereby forming a lower interconnect groove 11a. Next, a first barrier metal film 12a made of a Ta/TaN multilayer film and a copper seed film (not shown) are successively deposited on the cap film and the first interlayer insulating film 11 by sputtering to fill halfway the lower interconnect groove 11a formed in the cap film and the first interlayer insulating film 11. Subsequently, a first copper film 12b is deposited on the copper seed film by electrolytic plating to completely fill the lower interconnect groove 11a. Subsequently, respective parts of the first barrier metal film 12a and the first copper film 12b located outside the lower interconnect groove 11a and the cap film are removed by CMP (hereinafter, these two films are considered as a multilayer including also the copper seed film interposed therebetween), thereby forming a lower interconnect 12 composed of the first barrier metal film 12a and the first copper film 12b.

Next, the exposed top surface of the first interlayer insulating film 11 is located below the top surface of the lower interconnect 12 in the same manner as in the second *embodiment. As a result, in a later process step, a second interlayer insulating film 14 is formed so as to be bonded to the first interlayer insulating film 11, and therefore the interface between the first and second interlayer insulating films 11 and 14 can be located below the top surface of the lower interconnect 12.

Next, as shown in FIG. 8B, a hydrophilic barrier film 13 made of, for example, a silicon carbide film and functioning as a film for preventing the diffusion of copper is deposited on the lower interconnect 12 and the first interlayer insulating film 11 to have a thickness of approximately 50 nm. In this case, the top surface of the lower interconnect 12 is different in level from the top surface of the first interlayer insulating film 11. Therefore, a barrier film 13 is formed on the side surface of the lower interconnect 12 to partly form a sidewall.

Next, as shown in FIG. 8C, a resist pattern (not shown) is formed on the barrier film 13 by photolithography to mask the lower interconnect 12 and part of the barrier film 13 forming a sidewall, and then the barrier film 13 is subjected to dry etching using the resist pattern as a mask. In this way, the barrier film 13 is left on the top and side surfaces of the lower interconnect 12. Alternatively, a conductive barrier film 13 of, for example, CoWP can be selectively deposited on the top and side surfaces of the lower interconnect 12, for example, by p-CVD. Thereafter, as shown in FIG. 8C, a hydrophobic second interlayer insulating film 14 made of, for example, a silicon oxide film containing carbon is deposited on the first interlayer insulating film 11 and the barrier film 13 to have a thickness of approximately 600 nm.

The fabrication method for an electronic device according to the fourth embodiment of the present invention is characterized as follows: the first interlayer insulating film 11 is directly bonded to the second interlayer insulating film 14; the interface at which the first and second interlayer insulating films 11 and 14 are bonded to each other is located below the top surface of the lower interconnect 12; and, in addition, the barrier film 13 partly has a sidewall on the side surface of the lower interconnect 12. Since in this case there exists an interface between the first interlayer insulating film 11 and the second interlayer insulating film 14 that are both hydrophobic, this provides excellent adhesion at the interface between the first interlayer insulating film 11 and the second interlayer insulating film 14. This can prevent the separation between the first interlayer insulating film 11 and the second interlayer insulating film 14 at the interface therebetween. Therefore, the known problem of the separation between a hydrophobic interlayer insulating film and a hydrophilic barrier film at the interface therebetween can be solved. Moreover, since the interface at which the first and second interlayer insulating films 11 and 14 are bonded to each other, though serving as a path through which copper is likely to diffuse into the interlayer insulating films, is located below the top surface of the lower interconnect 12, copper can be restrained from diffusing from the lower interconnect 12 into the interlayer insulating films. Furthermore, since part of a barrier film 13 forms a sidewall on the side surface of the lower interconnect 12, this increases the length of the interface at which copper diffuses from the lower interconnect 12 into the interlayer insulating films. Therefore, copper can be restrained from diffusing from the lower interconnect 12 into the interlayer insulating films. More particularly, since the interface between the lower interconnect 12 and the second interlayer insulating film 14, at which copper diffuses from the lower interconnect 12 into the interlayer insulating films, is completely covered with part of the barrier film 13 serving as a sidewall, this increases the energy gap beyond which copper atoms should go to diffuse into the interlayer insulating films. Therefore, copper can be restrained from diffusing from the lower interconnect 12 into the interlayer insulating films. This can improve the reliability of the copper interconnect. Furthermore, since a barrier film 13 with a high permittivity is neither formed nor deposited on the first interlayer insulating film 11, this significantly reduces the interconnect capacitance. Therefore, the problem of an interconnect delay for an electronic device can be solved.

Furthermore, in this embodiment, when the height of the lower interconnect 12 is 250 nm or less, the interface at which the first and second interlayer insulating films 11 and 14 are bonded to each other is preferably located 10 nm or more below the top surface of the lower interconnect 12.

Although a description was given above of the case where the first and second interlayer insulating films 11 and 14 are both hydrophobic, a hydrophilic material, such as nanoporous-silica-based material (for example, nano clustering silica (NCS)), may be used as a material used for both the first and second interlayer insulating films 11 and 14 in this embodiment. Since as described above the first and second interlayer insulating films 11 and 14 are both hydrophilic, this can improve the adhesion between the first and second interlayer insulating films 11 and 14, leading to the prevention of the separation therebetween at their interface.

Furthermore, the first and second interlayer insulating films 11 and 14 are preferably made of a film having a low permittivity of 2.4 or less to reduce the electrical parasitic capacitances between interconnects.

Although a description was given above of the case where copper is used as a material for interconnects (the lower interconnect 12 and the upper interconnect 16), the type of the material for interconnects is not particularly limited in this embodiment. For example, copper, silver, aluminum, or their alloys may be used.

Moreover, in this embodiment, the length obtained by summing the width of the lower interconnect 12 and the distance between the lower interconnect 12 and an interconnect adjacent to the lower interconnect 12 is preferably 0.4 μm.

Although a description was given above of the case where the Ta/TaN multilayer film is used for the barrier metal films (the first barrier metal film 12a and the second barrier metal film 16a), the type of the barrier metal films is not particularly limited in this embodiment. For example, a Ta film, a TaN film, a WN film, a TiN film, or their multilayer film may be used.

Although a description was given above of the case where a silicon carbide film (SiC film) is used for the barrier film 13, the type of the barrier film 13 is not particularly limited in this embodiment. An insulative barrier film made of any one selected from the group of, for example, a SiN film (silicon nitride film), a SiCN film (silicon carbide nitride film), a SiC film, a SiCH film, and a BCB film (benzocyclobutene film) or a conductive barrier film made of any one selected from the group of, for example, a CoWP film and a CoWB (cobalt tungsten boride) film can be used for the barrier film 13.

Although a description was given above of the case where a first barrier metal film 12a is formed over the side and bottom surfaces of the lower interconnect 12, a first barrier metal film 12a does not have to be formed in the lower interconnect groove 11a in this embodiment. Even in this case, not only when a material other than the above-described copper is used as a material for a lower interconnect but also when copper that is likely to diffuse into the interlayer insulating films is used thereas, the reduced interconnect resistance can be achieved as compared with the known structure of an electronic device in which a barrier film is interposed between first and second interlayer insulating films, and the known problem of the separation between films at their interface can be solved.

Furthermore, also in this embodiment, an interface between the first interlayer insulating film 11 and the second interlayer insulating film 14 may be formed to become uneven in the method described in the third embodiment. In this case, not only the above-described effects but also the following effects can be achieved. The uneven interface increases the area in which the first interlayer insulating film 11 comes into contact with the second interlayer insulating film 14 at their interface. Therefore, the adhesion at their interface is sharply improved. In addition, copper can be restrained from diffusing into the interlayer insulating films because of the increased length of the interface between the first and second interlayer insulating films 11 and 14, which serves as a path through which copper diffuses into the interlayer insulating films. This can improve the reliability of the copper interconnect.

As described above, the present invention is useful for an electronic device and a fabrication method for the same, in particular, when applied to a high-reliability copper interconnect structure or the like using a damascene process.

What is claimed is:

1. An electronic device comprising:
a lower interconnect formed to fill a recess of a first insulating film;
a barrier film formed at least on the lower interconnect; and
a second insulating film formed over the first insulating film and the barrier film,
wherein the first and second insulating films are bonded to each other.

2. The electronic device of claim 1, wherein
the interface at which the first and second insulating films are bonded to each other is located below the top surface of the lower interconnect.

3. The electronic device of claim 2, wherein
the barrier film is formed to cover part of the side surface of the lower interconnect located at a higher level than the interface at which the first and second insulating films are bonded to each other.

4. The electronic device of claim 1, wherein
the interface at which the first and second insulating films are bonded to each other is uneven.

5. The electronic device of claim 4, wherein
for the surface roughness of the interface at which the first and second interlayer insulating films are bonded to each other, the arithmetic average roughness Rₐ thereof is 4 nm or less or the maximum height Rₘₐₓ thereof is 50 nm or less.

6. The electronic device of claim 1, wherein
the first and second insulating films are composed of films with the same properties.

7. The electronic device of claim 1, wherein
the first and second insulating films are composed of hydrophobic films or hydrophilic films.

8. The electronic device of claim 1, wherein
the barrier film is formed only on the lower interconnect.

9. The electronic device of claim 1, wherein
the barrier film is an insulative barrier film made of any one selected from the group of SiN, SiCN, SiC, SiCH, and BCB or a conductive barrier film made of any one selected from the group of CoWP and CoWB.

10. The electronic device of claim 1 further comprising
an upper interconnect formed in the second insulating film and electrically connected to the lower interconnect.

11. The electronic device of claim 1, wherein
the upper interconnect is electrically connected to the lower interconnect through a plug whose lower end is connected to the lower interconnect and whose upper end is connected to the upper interconnect.

12. The electronic device of claim 1, wherein
the lower interconnect has a copper interconnect structure in which its surfaces excluding its top surface are covered with a barrier metal layer.

13. The electronic device of claim 1, wherein
the length obtained by summing the width of the lower interconnect and the distance between the lower interconnect and an interconnect adjacent to the lower interconnect is 0.4 μm or less.

14. The electronic device of claim 2, wherein
the height of the lower interconnect is 250 nm or less, and
the interface at which the first and second interlayer insulating films are bonded to each other is located 10 nm or more below the top surface of the lower interconnect.

15. The electronic device of claim 1, wherein
the first interlayer insulating film is made of a film having a low permittivity of 2.4 or less.

16. A method for fabricating an electronic device, the method comprising the steps of:
forming a recess in a first interlayer insulating film;
forming a conductive pattern to fill the recess;
forming a barrier film at least on the conductive pattern; and
forming a second insulating film on the first insulating film and the barrier film,
wherein the step of forming the second insulating film is carried out to produce an interface at which the first and second insulating films are bonded to each other.

17. The method of claim 16, wherein
the step of forming the barrier film comprises the step of depositing the barrier film on the first insulating film and the conductive pattern, then forming a resist pattern to mask an area occupied by the conductive pattern, and selectively removing the deposited barrier film using the resist pattern.

18. The method of claim 16, wherein
the step of forming the barrier film is carried out using selective CVD.

19. The method of claim 16, wherein
the interface at which the first and second insulating films are bonded to each other is formed so as to be located below the top surface of the conductive pattern.

20. The method of claim 19, wherein
the step of forming the conductive pattern comprises the step of depositing a conductive film to fill the recess and then removing part of the conductive film located outside the recess using a polishing slurry with a higher removal rate for the first insulating film than that for the conductive film.

21. The method of claim 16 further comprising the step of, after the step of forming the conductive pattern and before the step of forming the barrier film, selectively removing the exposed top surface of the first insulating film.

22. The method of claim 21, wherein
the step of selectively removing the exposed top surface of the first insulating film is carried out by a plasma process or a cleaning process using a chemical solution.

23. The method of claim 22, wherein
the plasma process is carried out using a plasma made of any one or more selected from the group of O₂, H₂, H₂O, N₂, He, and NH₃.

24. The method of claim 22, wherein
the cleaning process using the chemical solution is carried out using a chemical solution of HF or a chemical solution of a polymer containing quarternary ammonium salt.

25. The method of claim 22, wherein
in the step of forming the barrier film, the barrier film is formed to cover part of the side surface of the lower interconnect located at a higher level than the top surface of the first insulating film.

26. The method of claim 16, wherein
the interface at which the first and second insulating films are bonded to each other is formed to become uneven.

27. The method of claim 26, wherein
the step of forming the conductive pattern includes the step of depositing a conductive film to fill the recess, removing part of the conductive film located outside the recess, and then polishing the exposed top surface of the first insulating film using slurry with an abrasive grain density of 20 wt % or more.

28. The method of claim 26 further comprising the step of, after the step of forming the conductive pattern and before the step of forming the barrier film, subjecting the exposed top surface of the first insulating film to a plasma process.

29. The method of claim 28, wherein
the plasma process is carried out using a mixed gas of Ar and H₂, a mixed gas of Ar and He, a mixed gas of NH₃ and He, or a mixed gas of NH₃ and H₂.
